(19) United States
(12) Patent Application Publication
(10) Pub. No.: US 2023/0411505 A1
(43) Pub. Date: Dec. 21, 2023

(54) HIGH LINEARITY FET WITH BURIED GATE STRUCTURES AND TAPERED CHANNEL LAYER

(71) Applicant: Teledyne Scientific & Imaging, LLC, Thousand Oaks, CA (US)

(72) Inventors: Keisuke Shinohara, Thousand Oaks, CA (US); Dean Regan, Simi Valley, CA (US); Casey King, Newbury park, CA (US)

(21) Appl. No.: 18/130,838

(22) Filed: Apr. 4, 2023

Related U.S. Application Data
(60) Provisional application No. 63/352,564, filed on Jun. 15, 2022.

(51) Int. Cl. H01L 29/778; H01L 29/20; H01L 29/423

(52) U.S. Cl. CPC H01L 29/7786; H01L 29/42316; H01L 29/2003

(57) ABSTRACT

A FET with buried gate structures which contact an epitaxial channel layer only from the sides. The epitaxial channel layer preferably comprises multiple channel segments, the widths of which vary along the depth direction. By controlling the slope of the channel sidewalls and the distance between buried gate structures, the FET's transfer characteristics can be engineered to improve the FET's linearity.

### RELATED APPLICATIONS

This application claims the benefit of provisional patent application No. 63/352,564 to Keisuke Shinohara et al., filed Jun. 15, 2022.

### BACKGROUND OF THE INVENTION

### Field of the Invention

This invention relates generally to field-effect transistors (FETs), and more particularly to FETs employing buried gate structures and a channel width that varies with depth to engineer transfer characteristics which improve device linearity.

### Description of the Related Art

In most conventional field effect transistors (FETs), the gate electrode is formed on the top of a semiconductor surface to modulate the drain current by the use of a vertical gate electric field. This forms a region at the drain end of the gate where electric field strength becomes the highest during high voltage operation. This is a primary cause of critical problems for conventional FETs. For example, current collapse caused by electron trapping at the drain end of the gate on the semiconductor surface is a commonly known problem which degrades RF power performance (output power, efficiency, linearity, gain) of FETs when they are operated to provide a large voltage swing. For GaN-based high electron mobility transistors (HEMTs) with strong piezoelectricity, the high vertical electric field at the drain end of the gate can cause cracks in the epitaxial layers by inducing tensile stress in the top barrier material (so-called “inverse piezoelectric effect”). This effect limits the reliability of GaN-based HEMTs.

Further problems can arise when operating FETs at high frequencies. For example, for conventional FETs, electrostatic isolation is degraded when the gate length is scaled down for high frequency operations (“short channel effects”). This limits a FET's gain and can degrade its off-state leakage and breakdown voltage characteristics. Additionally, although a low knee voltage is preferred for high efficiency operation of power amplifiers (PAs) and low noise operation of low noise amplifiers (LNAs), knee voltage is largely limited by parasitic resistances arising from metal-semiconductor contact resistance and device access resistances. Ideally, when the drain-source voltage is low (in the ohmic region), all the voltage is applied only in the intrinsic active PET region for early channel pinch-off, without an excess voltage drop in parasitic resistances to decrease Vknee.

For high linearity operation, a gradual gin curve is preferred because abrupt change in the gin curve results in large gm derivatives (gm′ & gm″), which degrade the transistor's linearity performance. In conventional HEMTs with a top gate contact, the gm curve typically shows a peak, which is due to their operation principle that uses electron density modulation by the vertical gate field. In conventional metal-semiconductor field-effect transistors (MESFETs), the gm curve is more gradual due to their mode of operation, but the electron velocity is lower than HEMTs due to increased scattering by ionized impurities in the channel, limiting their operational frequencies.

During high power operation of a PET, dissipated power turns into heat (“self-heating”). This limits output power, gain, and efficiency of PAs. In addition, an increased junction temperature reduces the lifetime of the transistors. In a conventional PET, the junction temperature peaks at the drain end of the gate where the electric field is the highest, and the peak junction temperature increases with increasing device periphery, i.e., gate width.

MESFETs are known to be more linear than high electron mobility transistors (HEMTs). One device-level linearization technique that has been used in MESFETs is optimizing a doping profile for a linear gm profile (see, e.g., Jose Pedro, “MESFET linearity improvement by channel doping control”, 1527-1530, vol. 3, 10.1109/MWSYM (1995)). Drawbacks of MESFETs are their lower frequency and noise performances with respect to HEMTs.

A device known as a Superlattice Castellated Field Effect Transistor (SLCFET)-described, for example, in U.S. Pat. No. 9,202,906—employs a structure having multiple 2DEG channels and a tri-gate (i.e., with both top and lateral contacts), where the threshold voltage of the channels is determined by both vertical and lateral electric fields.

### SUMMARY OF THE INVENTION

A FET with buried gate structures and a tapered channel layer is presented, in which the buried gate structures contact an epitaxial channel layer only from the sides. The gates do not contact the FET's top surface, and hence drain current is controlled only by channel width modulation by lateral gating of the channel layers by the buried gate structures.

The epitaxial channel layer comprises multiple channel segments, each of which has a width defined as the distance between adjacent ones of the buried gate structures. As described herein, the FET is fabricated such that the channel segment widths ‘taper’— i.e., the widths vary along the depth direction. By controlling the slope of the channel sidewalls and the distance between buried gate structures, the FET's transfer characteristics can be engineered to improve its linearity. For example, a FET has an associated transconductance (gm). As described herein, the slope of the channel sidewalls can be controlled to minimize gm″ and the slope of the gm″−Vgs curve near the point at which gm″=0. High gm/gm″ is known to improve a FET's linearity.

By having the channel segment widths vary as described herein, the threshold voltages of the channel segments also vary along the depth direction. This results in the FET having multiple transfer curves, which are superposed to provide the FET's overall transfer characteristic.

The present FET may comprise multiple epitaxial channel layers stacked in the depth direction, each of which comprises a two-dimensional electron gas (2DEG) plane. Alternatively, the device may comprise a single uniformly doped epitaxial channel layer having a width that varies along the depth direction. The concepts descried herein can be applied to multiple FET types, including HEMTs and MESFETs.

These and other features, aspects, and advantages of the present invention will become better understood with reference to the following drawings, description, and claims.

### BRIEF DESCRIPTION OF THE DRAWINGS

FIG. 1 is a perspective view of a HEMT employing buried gate structures.

FIG. 2 is a sectional view of one possible embodiment of a multi-channel FET per the present invention.

FIG. 3 is a photomicrograph of a channel segment having tapered sidewalls as described herein.

FIG. 4 is a graph depicting multiple and superposed transfer curves as can be achieved with the present FET.

FIGS. 5A and 5B are graphs illustrating gm and gm″ performance for a conventional HEMT and a HEMT as described herein, respectively.

FIG. 6 is a sectional view of another possible embodiment of a multi-channel FET per the present invention.

FIG. 7 is a sectional view of a possible embodiment of a FET with a uniformly doped channel layer per the present invention.

FIG. 8 is a sectional view of another possible embodiment of a FET with a uniformly doped channel layer per the present invention.

### DETAILED DESCRIPTION OF THE INVENTION

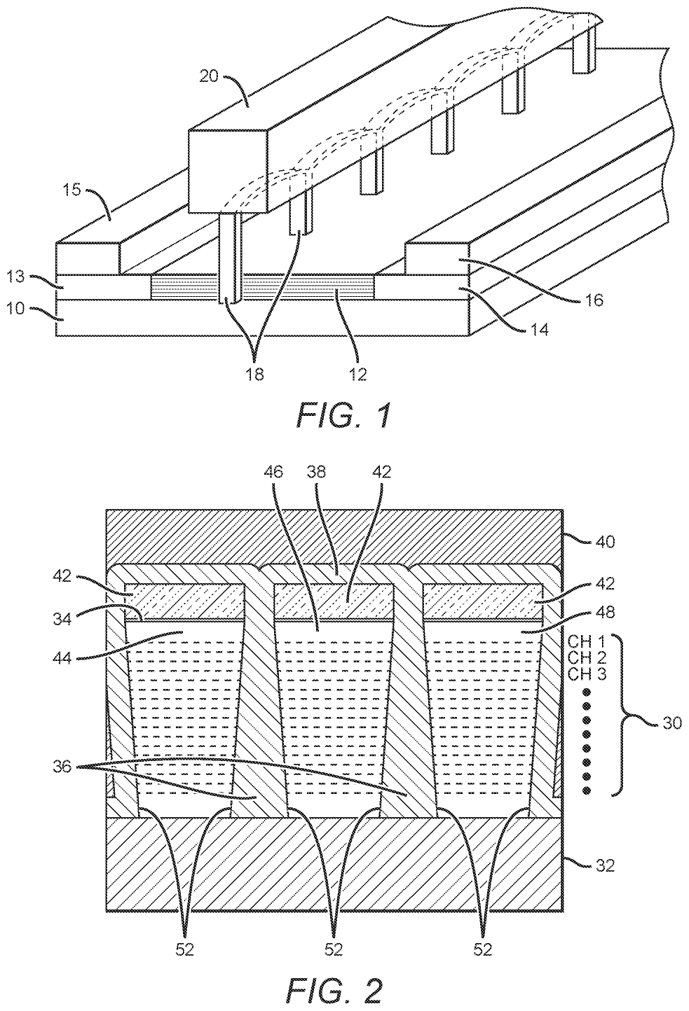

An exemplary embodiment of a FET with a buried gate structure is illustrated in FIG. 1; this device structure is described in detail in U.S. Pat. No. 10,388,746. The FET includes a substrate 10, multiple 2DEG channels 12 on the substrate, source and drain contacts 13, 14 (suitably regrown n+GaN) adjacent channels 12 with source and drain electrodes 15, 16 on the top surface of the contacts, and a gate electrode. The gate electrode comprises a plurality of buried gate structures 18, the tops of which extend above the top surface of substrate 10 and the bottoms of which are buried to a depth at least equal to that of the bottom of the current-carrying portion of the lowermost of 2DEG channels 12, such that the buried gate structures contact the channel layers only from the sides. In this example, the FET is a high electron mobility transistor (HEMT). A head portion 20 above and not in contact with the top surface of substrate 10 interconnects all of buried gate structures 18. When so arranged, the FET's drain current is controlled by channel width modulation by lateral gating of the channel layers by buried gate structures 18. Note that as used herein, the substrate's “top surface” refers to the surface of the uppermost epitaxial layer that has been grown on the substrate.

As shown in FIG. 1, a FET with a buried gate structure might include multiple stacked channel layers, each with its own 2DEG plane. This type of multi-channel structure serves to increase current density and achievable output power (Pout) for the FET, while utilizing the high-speed characteristics of 2DEG for high frequency performance, without increasing the device footprint.

Active devices are a prime source of non-linearity in RF circuits. The present invention reduces the nonlinear behavior of FETs through material and device co-design, employing a new transistor structure that improves device-level linearity by engineering a desired transconductance (gm) profile. One possible embodiment of the present device structure is illustrated in the sectional view of FIG. 2. Here, the device comprises multiple stacked epitaxial channel layers (CH 1, CH 2, CH 3, . . . ) 30 on a substrate 32 which has a top surface 34. Source and drain contacts and electrodes (not shown) would be similar to those shown in FIG. 1, with the contacts formed laterally to channel layers 30 and the electrodes present on the top surface of the contacts. A gate electrode comprises a plurality of buried gate structures 36, the tops of which (38) extend above top surface 34 and the bottoms of which are buried to a depth at least equal to that of the bottom of the current-carrying portion of the lowermost epitaxial channel layer, such that the buried gate structures contact the epitaxial channel layers only from the sides. A head portion 40 above and not in contact with top surface 34 contacts and interconnects all of buried gate structures 36. A dielectric material 42 is between top surface 34 and head portion 40; suitable dielectric materials include SiN, SiO₂, BCB, or air. The FET's drain current is controlled by channel width modulation by lateral gating of epitaxial channel layers 30 by buried gate structures 36.

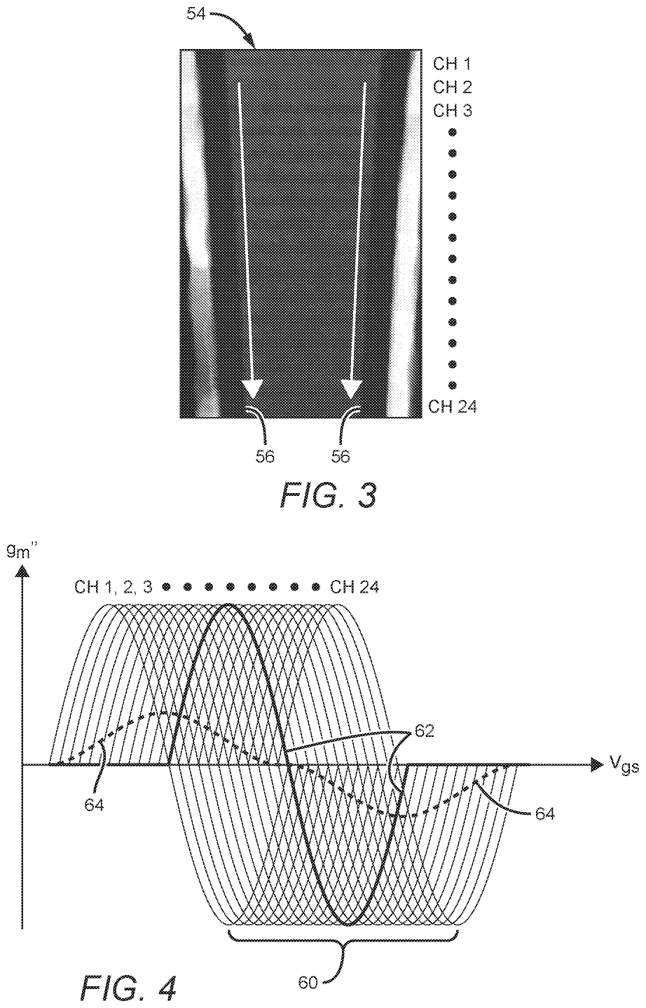

When so arranged, epitaxial channel layers 30 comprise multiple channel segments, such as channel segments 44, 46, 48. Each channel segment has a width defined as the distance between adjacent ones of buried gate structures 36. To engineer a desired transconductance (gm) profile, the FET is fabricated such that the channel segment widths vary along the depth direction. For example, in FIG. 2, channel segments 44, 46, 48 are arranged such that their widths become narrower with depth. Each of the multiple channel segments has associated sidewalls 52. The slope of sidewalls 52 can be controlled to create the variation in channel segment widths, and to thereby provide a desired transfer characteristic for the FET. A photomicrograph of a channel segment 54 having tapered sidewalls 56 as described herein is shown in FIG. 3.

By tapering the channel segments in this way, each channel has a slightly different threshold voltage. This is illustrated in the graph shown in FIG. 4. The graph assumes 24 channel segment layers, each with a slightly different width and threshold voltage, resulting in multiple transfer curves 60. Whereas channels having a single width produce a single transfer curve such as curve 62, multiple transfer curves 60 are superposed to provide the FET's overall transfer characteristic 64. In practice, the slope of the channel segment sidewalls is preferably controlled to minimize gm″ and the slope of the gm″−Vgs curve near the point at which gm″=0, leading to improved FET linearity as compared to FET structure having a single channel width.

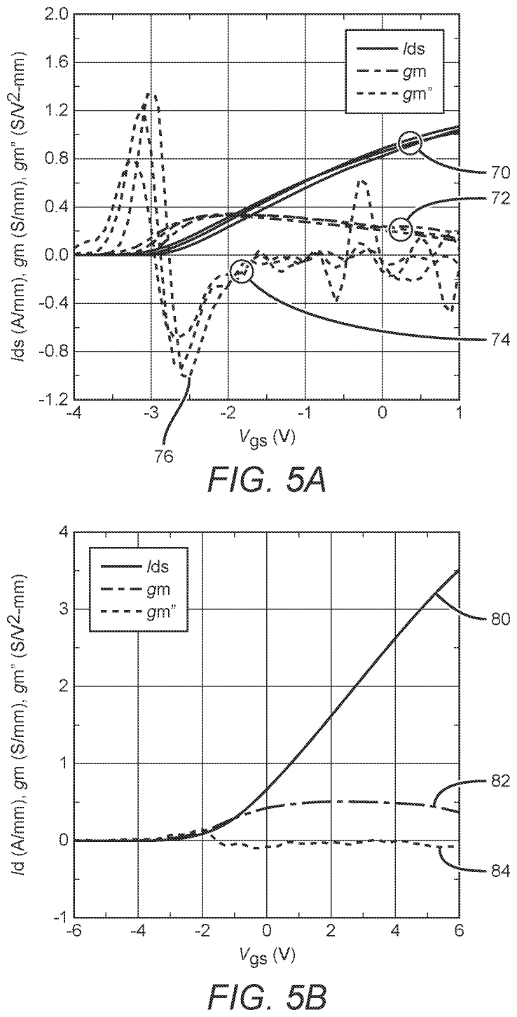

FIG. 5A is a graph illustrating Ids (70), gm (72), and gm″ (74) with respect to Vgs for three values of Vds for a conventional top-gate GaN-HEMT. The gm″ value exhibits abrupt pinch-off at point 76; here, |gm/gm″|=0.26 V⁻², and the gm curve rolls off with increasing Vgs.

FIG. 5B is a graph illustrating Ids (80), gm (82), and gm″ (84) with respect to Vgs for a Vds value of 4V for an exemplary multi-channel HEMT as described herein. Here, |gm/gm″|=4.1 V⁻², and the gm curve is broad and flat with gm=0.5 S/mm. A high value of gm/gm″ is known to improve a FET's linearity.

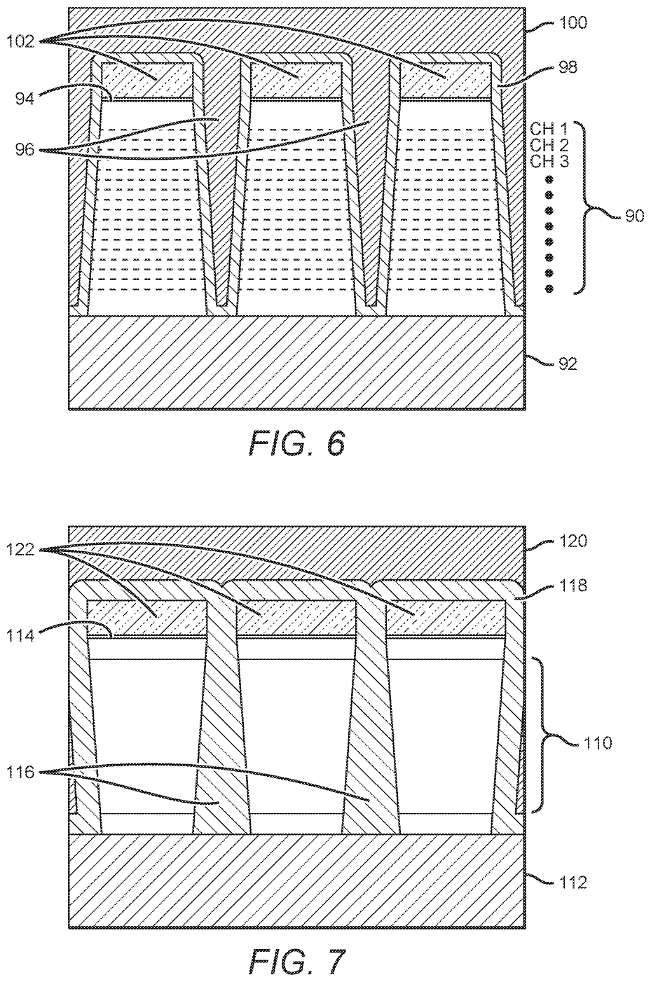

As shown in FIG. 2, the multiple channel segments of a FET as described herein may be arranged such that their widths become narrower with depth. The FET might also be arranged such that the channel segment widths become wider with depth; this is illustrated in the sectional view of FIG. 6, which depicts another possible embodiment of a multi-channel FET as described herein. Multiple stacked epitaxial channel layers (CH 1, CH 2, CH 3, . . . ) 90 are on a substrate 92 which has a top surface 94. Source and drain contacts and electrodes (not shown) would be similar to those shown in FIG. 1, with the contacts formed laterally to channel layers 90 and the electrodes present on the top surface of the contacts. A gate electrode comprises a plurality of buried gate structures 96, the tops of which (98) extend above top surface 94 and the bottoms of which are buried to a depth at least equal to that of the bottom of the current-carrying portion of the lowermost epitaxial channel layer, such that the buried gate structures contact the epitaxial channel layers only from the sides. A head portion 100 above and not in contact with top surface 94 contacts and interconnects all of buried gate structures 96. A dielectric material 102 is between top surface 94 and head portion 100; suitable dielectric materials include SiN, SiO₂, BCB, or air. The FET's drain current is controlled by channel width modulation by lateral gating of epitaxial channel layers 90 by buried gate structures 96.

One possible embodiment of the present FET is a HEMT in which the current-carrying portion of the epitaxial channel layer comprises a 2DEG plane. As shown in FIGS. 2, 3, and 6, The epitaxial channel layer preferably comprises multiple epitaxial channel layers stacked in the depth direction, each of which comprises a 2DEG plane. The HEMT's top surface suitably comprises GaN, with each of the multiple epitaxial channel layers comprising an AlGaN barrier and a GaN channel; the 2DEG is formed at AlGaN/GaN hetero interface. Other possible material combinations for the epitaxial channel layers include AlₓGa₁₋ₓN/Al_{y}Ga_{1-y}N (x>y), AlGaAs/(In)GaAs, InAlAs/InGaAs, or (AlₓGa₁₋ₓ)₂O₃/Ga₂O₃.

Suitable materials for buried gate structures as described herein comprise metals, or p-type semiconductors (p-type NiO material, p-type GaN material, p-type CuS material, or a stack comprising a gate dielectric and a metal). Suitable metals include Pt, Ni, or Au. A suitable stack might include Al₂O₃/Pt or HfO₂/Pt. Alternatively, the buried gate structures might comprise p-type NiO material, p-type GaN material, or p-type CuS material.

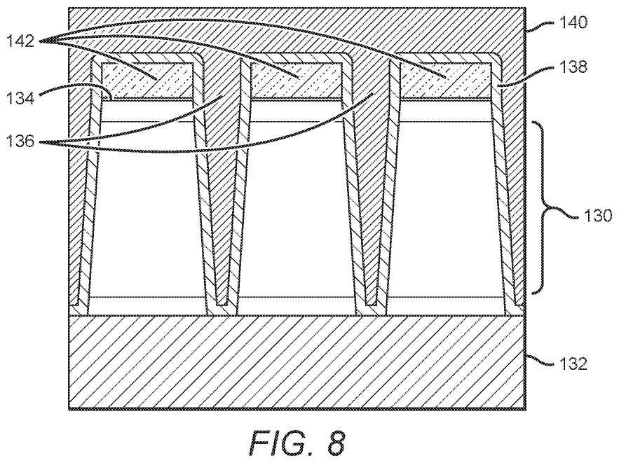

A FET with a tapered channel layer as described herein might also be employed in a device with a single uniformly doped channel layer. This is illustrated in the sectional views shown in FIGS. 7 and 8. In FIG. 7, a single uniformly doped channel layer 110 is on a substrate 112. Source and drain electrodes (not shown) would be present on the channel's top surface 114. A gate electrode comprises a plurality of buried gate structures 116, the tops of which (118) extend above top surface 114 and the bottoms of which are buried to a depth at least equal to that of the bottom of the current-carrying portion of the channel layer, such that the buried gate structures contact the epitaxial channel layer only from the sides. A head portion 120 above and not in contact with top surface 114 contacts and interconnects all of buried gate structures 116. A dielectric material 122 is between top surface 114 and head portion 120; suitable dielectric materials include SiN, SiO₂, BCB, or air. The FET's drain current is controlled by channel width modulation by lateral gating of epitaxial channel layer 110 by buried gate structures 116.

Just as the multi-channel devices described above can be arranged such that the channel segments get narrower or wider with depth (as shown in FIGS. 2 and 6), the same applies to a device with a uniformly doped channel. FIG. 7 illustrates uniformly doped channel 110 getting narrower with depth, while FIG. 8 shows a device with a uniformly doped channel that gets wider with depth. Here, the device includes a uniformly doped channel 130 on a substrate 132 having a top surface 134. A gate electrode comprises a plurality of buried gate structures 136, the tops of which (138) extend above top surface 134. A head portion 140 above and not in contact with top surface 134 contacts and interconnects all of buried gate structures 136, with a dielectric material 142 between top surface 134 and head portion 140.

The buried gate structures can have any of a number of shapes. For example, the structures may be cylindrical, as shown in FIG. 1. They might also be, for example, rectangular, or any other suitable shape.

The buried gate structures preferably lie along a line which is parallel to and between the source and drain contacts, as illustrated in FIG. 1. The buried gate structures may be evenly spaced along such a line, or not evenly spaced. Note that the spacing between buried gate structures can also affect a FET's transfer characteristics. For example, the spacing between the buried gate structures may be selected to help achieve a desired I-V curve, particular values for gm and its derivatives (gm″ and gm′″), and/or threshold voltage. The buried gate structures are preferably fabricated using electron beam lithography, which enables extremely accurate control of the size of the structures and the pitch between them.

HEMTs are depicted in the examples shown, though the buried gate and tapered channel layer arrangement described herein could be applied to other FET types, including MESFETs. A MESFET per the present invention would have an epitaxial buffer layer on a substrate, and an epitaxial channel layer on the buffer layer. The channel layer would be as described above—i.e., with a width that varies along the depth direction. In one possible embodiment, the buffer layer suitably comprises GaN, and the epitaxial channel layer comprises n-type or p-type GaN. Other possible materials for the epitaxial buffer layer include Al(Ga)N, (In)GaAs, InP, or Ga₂O₃.

The depth to which the buried gate structures should be buried depends on the device type. As noted above, for a HEMT, the bottoms of the gate structures should be buried to a depth at least equal to the bottom of the current-carrying 2DEG plane in the lowermost channel layer. If the device is a MESFET, the buried gate structure should be buried to a depth at least equal to the bottom of the channel layer. In general, the buried gate structures must be buried deep enough so that they contact the current-carrying portion of the channel layer or layers only from their sides, such that the FET's drain current is controlled by channel width modulation by lateral gating of the current-carrying layer by the buried gates structures.

As noted above, the gap between the top of the substrate and the bottom of the gate electrode head portion is filled with a dielectric, such as SiN, SiO₂, BCB, or simply air. If a dielectric material is used, it should be thick enough so that the head portion does not modulate the FET current via the vertical gate field (through the dielectric).

A FET whose drain current is controlled only by channel width modulation by lateral gating of the current-carrying layer(s), and with channel layers having widths that vary along the depth direction, enables small variations and precise control in the threshold voltage for each channel, making it possible to achieve a very linear gm profile. Applications for the present FET include power amplifier (PA) MMICs with high linearity, and low noise amplifier (LNA) MMICs with high linearity.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

We claim:

1. A field-effect transistor (FET), comprising:
a substrate;
an epitaxial channel layer on said substrate;
source and drain electrodes; and
a gate electrode, comprising:
a plurality of buried gate structures, the tops of which extend above said substrate's top surface and the bottoms of which are buried to a depth at least equal to that of the bottom of the current-carrying portion of said epitaxial channel layer, such that said buried gate structures contact said epitaxial channel layer only from the sides of said epitaxial channel layer;
wherein said epitaxial channel layer comprises multiple channel segments, each of said channel segments having a width defined as the distance between adjacent ones of said buried gate structures, each of said channel segment widths varying along the depth direction; and
a head portion above and not in contact with said substrate's top surface which contacts and interconnects all of said buried gate structures;
such that said FET's drain current is controlled by channel width modulation by lateral gating of the channel layers by said buried gate structures.

2. The FET of claim 1, wherein each of said multiple channel segments has associated sidewalls, the slope of said sidewalls controlled to provide a desired transfer characteristic for said FET.

3. The FET of claim 2, said FET having an associated transconductance (gm), the slope of said sidewalls controlled to minimize gm″ and the slope of the gm″−Vgs curve near the point at which gm″=0.

4. The FET of claim 2, wherein said multiple channel segments are arranged such that their widths become narrower with depth.

5. The FET of claim 2, wherein said multiple channel segments are arranged such that their widths become wider with depth.

6. The FET of claim 1, wherein said current-carrying portion of said epitaxial channel layer comprises a two-dimensional electron gas (2DEG) plane.

7. The FET of claim 6, wherein said epitaxial channel layer comprises multiple epitaxial channel layers stacked in the depth direction, each of which comprises a 2DEG plane.

8. The FET of claim 7, wherein said FET's top surface comprises GaN and each of said multiple epitaxial channel layers comprises an AlGaN barrier and a GaN channel.

9. The FET of claim 7, wherein the threshold voltage of each of said channel segments varies along the depth direction.

10. The FET of claim 9, wherein said varied threshold voltages provide multiple transfer curves for said FET which are superposed to provide said FET's overall transfer characteristic.

11. The FET of claim 1, wherein said epitaxial channel layer is uniformly doped.

12. The FET of claim 1, wherein said FET is a high electron mobility transistor (HEMT).

13. The FET of claim 1, wherein said buried gate structures are cylindrical.

14. The FET of claim 1, wherein said buried gate structures are rectangular.

15. The FET of claim 1, wherein said plurality of buried gate structures lie along a line which is parallel to and between said source and drain electrodes.

16. The FET of claim 15, wherein said plurality of buried gate structures are evenly spaced along said line.

17. The FET of claim 15, wherein said plurality of buried gate structures are not evenly spaced along said line.

18. The FET of claim 1, wherein said FET is a metal-semiconductor field-effect transistor (MESFET), comprising:
an epitaxial buffer layer on said substrate; and
said epitaxial channel layer on said buffer layer.

19. The FET of claim 18, wherein said epitaxial buffer layer comprises GaN, and said epitaxial channel layer comprises n-type or p-type GaN on said buffer layer.

20. The FET of claim 18, wherein said epitaxial channel layer comprises n-type or p-type GaN, Al(Ga)N, (In)GaAs, InP, or Ga₂O₃.

21. The FET of claim 1, wherein said buried gate structures comprise metals, or p-type semiconductors (p-type NiO material, p-type GaN material, p-type CuS material, or a stack comprising a gate dielectric and a metal).

22. The FET of claim 21, wherein said metals comprise Pt, Ni, or Au.

23. The FET of claim 21, wherein said stack comprises Al₂O₃/Pt or HfO₂/Pt.

24. The FET of claim 1, wherein said buried gate structures comprise p-type NiO material.

25. The FET of claim 1, wherein said buried gate structures comprise p-type GaN material.

26. The FET of claim 1, wherein said buried gate structures comprise p-type CuS material.

27. The FET of claim 1, further comprising a dielectric material between said substrate's top surface and said head portion.

28. The FET of claim 27, wherein said dielectric material comprises SiN, SiO₂, BCB, or air.

29. The FET of claim 1, wherein said epitaxial channel layer comprises:
AlₓGa₁₋ₓN/Al_{y}Ga_{1-y}N (x>y),
AlGaAs/(In)GaAs,
InAlAs/InGaAs, or
(AlₓGa₁₋ₓ)₂O₃/Ga₂O₃.
